(19) United States
(12) Patent Application Publication
(10) Pub. No.: US 2010/0059365 A1
(43) Pub. Date: Mar. 11, 2010

(54) PROCESS FOR MANUFACTURING A MASK HAVING SUBMILLIMETRIC OPENINGS FOR PRODUCING A SUBMILLIMETRIC GRID, AND SUBMILLIMETRIC GRID

(75) Inventors: Emmanuel Valentin, Le Plessis Trevise (FR); Bernard Nghiem, Arsy (FR); Arnaud Huignard, Paris (FR); Georges Zagdoun, La Garenne Colombes (FR); Eddy Royer, Villemomble (FR)

Correspondence Address: OBLON, SPIVAK, MCCLELLAND MAIER & NEUSTADT, L.L.P., 1940 DUKE STREET, ALEXANDRIA, VA, 22314, US

(73) Assignee: SAINT-GOBAIN GLASS FRANCE, Courbevoie (FR)

(21) Appl. No.: 12/531,699

(22) PCT Filed: Mar. 21, 2008
(86) PCT No.: PCT/FR08/50505

§ 371 Date: Nov. 10, 2009

(30) Foreign Application Priority Data
Mar. 21, 2007 (FR) 0753972

(51) Int. Cl. C25D 17/10; B05D 1/32; B05D 1/36; B05D 5/12; C23C 14/04; C23C 14/34; C25D 5/02; B32B 3/10; B32B 17/06; H01L 31/0224; H01J 9/02; H05K 9/00; H05B 3/02

(52) U.S. Cl. 204/280; 427/256; 427/259; 427/58; 427/534; 427/569; 204/192.12; 205/118; 428/195.1; 428/210; 427/269; 136/252; 313/310; 174/392; 219/538

(57) ABSTRACT

A process for manufacturing a mask having submillimetric openings on a surface portion of a substrate, characterized in that:
a layer known as a mask layer is deposited from a solution of colloidal particles that are stabilized and dispersed in a solvent; and
the drying of the mask layer is carried out until a two-dimensional irregular network of substantially straight-edged interstices that gives a mask is obtained, with a random mesh of interstices in at least one direction.

Submillimetric grid obtained by the process.

One subject of the present invention is a process for producing a mask having submillimetric openings with a view to producing an optionally electrically conductive grid, especially for an electrochemical and/or electrically controllable device of the glazing type that has variable optical and/or energy properties, or a photovoltaic device, or else a light-emitting device, or even a heating device, or possibly a flat-lamp device.

Manufacturing techniques are known that make it possible to obtain micron-sized metal grids. These have the advantage of attaining surface resistances of less than 1 ohm/square while retaining a light transmission (T_{L}) of around 75 to 85%. However, these grids have a certain number of drawbacks:

their production process is based on a technique of etching a metal layer either via a photolithographic process combined with a process for chemical attack via a liquid route, or by a laser ablation technique. Whichever process is used, it results in a high manufacturing cost that is incompatible with the envisioned applications; and

the characteristic dimensions of these grids, generally of regular and periodic shape (square, rectangular), form networks of 20 to 30 μm wide metal strands spaced, for example, 300 μm apart, which are the source, when they are illuminated by a point light source, of diffraction patterns.

These manufacturing techniques of the prior art furthermore have a resolution limit of around a few tens of μm, leaving the patterns esthetically visible.

Document U.S. Pat. No. 7,172,822 describes the production of an irregular network conductor that is based on the use of a cracked silica sol-gel mask. In the examples carried out, a sol based on water, alcohol and a silica precursor (TEOS) was deposited, the solvent was evaporated and it was annealed at 120° C. for 30 minutes to form the 0.4 μm thick cracked sol-gel mask.

FIG. 3 from this document U.S. Pat. No. 7,172,822 reveals the morphology of the silica sol-gel mask. It appears in the form of fine crack lines oriented along a preferred direction, with bifurcations characteristic of the fracture phenomenon of an elastic material. These main crack lines are occasionally joined together by the bifurcations.

The domains between the crack lines are asymmetric with two characteristic dimensions: one parallel to the crack propagation direction between 0.8 and 1 mm, the other perpendicular between 100 and 200 μm.

Furthermore, masks which could be based on particles in solution are vaguely mentioned, without concrete exemplary embodiments.

This process for manufacturing an electrode by cracking of the sol-gel mask constitutes progress for the manufacture of a network conductor by eliminating, for example, recourse to photolithography (exposure of a resin to radiation/a beam and development), but may still be improved, especially in order to be compatible with industrial requirements (reliability, simplification and/or reduction of the manufacturing steps, reduced cost, etc.).

Furthermore, the electrical and/or optical properties of this irregular network electrode may be improved.

It can also be observed that the manufacturing process inevitably requires the deposition of a (chemically or physically) modifiable sublayer at the interstices in order to either allow a favored adhesion (of metal colloids, for example) or else to allow catalyst grafting for metal postgrowth, this sublayer therefore having a functional role in the growth process of the network.

Furthermore, the profile of the cracks is V-shaped due to the fracture mechanics of the elastic material, which involves the use of a post-mask process in order to make the metallic network grow starting from colloidal particles located at the base of the V.

The present invention therefore aims to overcome the drawbacks of the processes of the prior art by providing a process for manufacturing a submillimetric network that is irregular, in particular electrically conductive, economical, reproducible and controlled, and of which the optical properties and/or the electrical conductivity properties are at least comparable to those of the prior techniques.

For this purpose, a first subject of the invention is a process for manufacturing a mask having submillimetric openings on a surface portion of a substrate, especially a substrate having a glass function, comprising the following steps:

a mask layer is deposited, onto the substrate itself or onto a sublayer, from a solution of colloidal particles that are stabilized and dispersed in a solvent; and

the drying of the mask layer is carried out until a two-dimensional network of substantially straight-edged interstices that forms the mask is obtained, with a random, aperiodic mesh of interstices in at least one direction.

The average width A is submillimetric.

The network of interstices has substantially more interconnections than the cracked silica sol-gel mask. Via the process according to the invention, a mesh of openings, which may be distributed over the entire surface, is thus formed making it possible to obtain isotropic properties.

The mask thus has a random, aperiodic structure in at least one direction, or even in two (all) directions.

Owing to this particular process, it is possible to obtain, at a lower cost, a mask composed of random (shape and/or size), aperiodic units of suitable characteristic dimensions:

(average) width of the network A is micron-sized, or even nanoscale, in particular between a few hundreds of nanometers to a few tens of microns, especially between 200 nm and 50 μm;

(average) size of unit B is millimetric or even submillimetric, especially between 5 to 500 μm, or even 100 to 250 μm;

B/A ratio is adjustable, in particular, as a function of the nature of the particles, especially between 7 and 20 or even 40;

difference between the maximum width of the openings and the minimum width of the openings is less than 4, or even less than or equal to 2, in a given region of the mask, or even over the majority or the whole of the surface;

difference between the maximum mesh (unit) dimension and the minimum mesh dimension is less than 4, or even less than or equal to 2, in a given region of the mask, or even over the majority or even over the whole of the surface;

the amount of open mesh (non-opening, “blind” interstice) is less than 5%, or even less than or equal to 2%, in a given region of the mask, or even over the majority or the whole of the surface, therefore with a limited or even almost zero network rupture that is optionally reduced and can be suppressed by etching of the network;

for a given mesh, the majority or even all of the meshes in a given region or over the whole of the surface, the difference between the largest dimension that is characteristic of the mesh and the smallest dimension that is characteristic of the mesh is less than 2, in order to strengthen the isotropy; and

for the majority or even all of the segments of the network, the edges are constantly spaced, parallel, in particular on a scale of 10 μm (for example, observed with an optical microscope with a magnification of 200).

The width A may be, for example, between 1 and 20 μm, or even between 1 and 10 μm, and B may be between 50 and 200 μM.

This makes it possible to subsequently produce a grid defined by an average strand width substantially identical to the width of the openings and an (average) space between the strands substantially identical to the space between the openings (of a mesh). In particular, the sizes of the strands may preferably be between a few tens of microns to a few hundreds of nanometers. The B/A ratio may be chosen between 7 and 20, or even 30 to 40.

The meshes delimited by the openings are of diverse shapes, typically with three, four or five sides, for example predominantly with four sides, and/or of diverse size, distributed randomly and aperiodically.

For the majority or all of the meshes, the angle between two adjacent sides of one mesh may be between 60° and 110°, especially between 80° and 100°.

In one configuration, a main network is obtained with interstices (optionally approximately parallel) and a secondary network of interstices (optionally approximately perpendicular to the parallel network), the location and the distance of which are random. The secondary interstices have a width, for example, smaller than the main interstices.

Drying causes a contraction of the mask layer and friction of the nanoparticles at the surface resulting in a tensile stress in the layer which, via relaxation, forms the interstices.

Unlike the silica sol-gel, the solution is naturally stable, with nanoparticles that are already formed, and preferably does not contain (or contains a negligible amount of) a reactive element of polymer precursor type.

Drying results, in one step, in the elimination of the solvent and the formation of the interstices.

After drying, clusters of nanoparticles are thus obtained, clusters that are of variable size and are separated by the interstices that are themselves of variable size.

In order to obtain the openings throughout the entire depth, it is necessary to both:

choose particles of limited size (nanoparticles), in order to promote their dispersion, preferably with a characteristic (average) size between 10 and 300 nm, or even 50 and 150 nm; and

to stabilize the particles in the solvent (especially by treatment via surface charges, for example via a surfactant, by control of the pH), to prevent them from agglomerating together, from precipitating and/or from falling due to gravity.

In addition, the concentration of the particles is adjusted, preferably between 5%, or even 10% and 60% by weight, more preferably still between 20% and 40%. The addition of a binder is avoided.

The solvent is preferably water-based, or even entirely aqueous.

In a first embodiment, the colloid solution comprises polymeric nanoparticles (and preferably with a water-based, or even entirely aqueous, solvent).

For example, acrylic copolymers, styrenes, polystyrenes, poly(meth)acrylates, polyesters or mixtures thereof are chosen.

In a second embodiment, the solution comprises mineral nanoparticles, preferably of silica, alumina, or iron oxide.

Since the particles have a given glass transition temperature T_{g}, the deposition and drying may be carried out at a temperature below said temperature T_{g} for better control of the morphology of the grid mask.

The deposition and drying steps of the process may especially be carried out (substantially) at ambient temperature, typically between 20° and 25° C. Annealing is not necessary.

The difference between the given glass transition temperature T_{g} of the particles and the drying temperature is preferably greater than 10° C., or even 20° C.

The deposition and drying steps of the process may be carried out substantially at atmospheric pressure rather than drying under vacuum, for example.

It is possible to deposit a solution (aqueous or non-aqueous) of colloids via a standard liquid route technique.

As wet route techniques, there is spin coating, curtain coating, dip coating, spray coating and flow coating.

It is possible to modify the drying parameters (control parameters), especially the degree of moisture and the drying rate, in order to adjust B, A, and/or the B/A ratio.

The higher the moisture is (all things otherwise being equal), the lower A is.

The higher the temperature is (all things otherwise being equal), the higher B is.

It is possible to modify other control parameters chosen from the friction coefficient between the compacted colloids, especially by nanotexturization of the substrate, and the surface of the substrate, the size of the nanoparticles and the initial particle concentration, the nature of the solvent and the thickness that is dependent on the deposition technique, in order to adjust B, A and/or the B/A ratio.

The thickness of the mask may be submicron-sized up to several tens of microns. The thicker the mask layer is, the larger A (respectively B) is.

The higher the concentration is (all things otherwise being equal), the lower B/A is.

The edges of the mask are substantially straight, that is to say along a midplane between 80 and 100° relative to the surface, or even between 85° and 95°.

Due to the straight edges, the deposited layer discontinues (no or little deposition along the edges) and it is thus possible to remove the coated mask without damaging the grid. For reasons of simplicity, directional techniques for deposition of the grid material may be favored. The deposition may be carried out both through the interstices and over the mask.

It is possible to clean the network of interstices using an atmospheric pressure plasma source.

In addition, the following may be carried out:

after drying, a heat treatment (that may or may not be local) at a temperature above the T_{g}, especially 3 times to 5 times the T_{g}, and naturally below the melting temperature Tₘ;

or a differential drying of the mask, for example by locally modifying the degree of moisture and/or the temperature.

This makes it possible to modify, locally or over the entire surface, the shape of the units and/or the size of the openings.

The studs are composed of a cluster of nanoparticles: under the action of temperature, these studs are capable of densifying. After densification, the size of the studs (B) is reduced: their surface and also the thickness are reduced. There is thus, via this heat treatment, modification in the characteristic dimensions of the mask: ratio of the mesh opening to the mesh width.

The compaction of the mask, as a second advantage, causes an improvement in the adhesion of this mask to the substrate which makes it more manipulable (prevents it from chipping) while retaining the possible lift-off steps (simple washing with water when the colloid has been deposited from an aqueous solution).

Via thermal treatment for compaction of the colloid mask it is therefore possible to modify—locally or over the entire surface—its characteristic dimensions without resorting to a new mask (as is the case for photolithography or etching). It is then possible to locally modify the shape of the meshes (width, height) and in the case of a conductive network to create zones having a conductivity gradient. It can be locally heated while keeping the rest cold.

Preferably, the heating time is adjusted as a function of the treatment temperature. Typically, the time is less than 1 h, preferably from 1 min to 20 min.

The modified zone or zones may be peripheral or central, and of any shape.

The surface for the deposition of the mask layer is a film-forming surface, in particular a hydrophilic surface if the solvent is aqueous. This is the surface of the substrate: glass, plastic (for example, polycarbonate) or of an optionally functional added sublayer: hydrophilic layer (silica layer, for example on plastic) and/or an alkali-metal barrier layer and/or a layer for promoting the adhesion of the grid material, and/or a (transparent) electrically conductive layer, and/or a decorative, colored or opaque layer.

This sublayer is not necessarily a growth layer for an electrolytic deposition of the grid material.

Between the mask layer there may be several sublayers.

The substrate according to the invention may thus comprise a sublayer (especially a base layer, closest to the substrate) that is continuous and capable of being a barrier to alkali metals.

It protects the grid material from any pollution (pollution which may lead to mechanical defects such as delaminations), in the case of an electrically conductive deposition (to form an electrode in particular), and additionally preserves its electrical conductivity.

The base layer is robust, quick and easy to deposit according to various techniques. It can be deposited, for example, by a pyrrolysis technique, especially in the gas phase (technique often denoted by the abbreviation CVD for “chemical vapor deposition”). This technique is advantageous for the invention since suitable adjustments of the deposition parameters make it possible to obtain a very dense layer for a reinforced barrier.

The base layer may optionally be doped with aluminum and/or boron to render its deposition under vacuum more stable. The base layer (a single layer or multilayer, optionally doped) may have a thickness between 10 and 150 nm, more preferably still between 15 and 50 nm.

The base layer may preferably be:
based on silicon oxide, silicon oxycarbide, a layer of general formula SiOC,
based on silicon nitride, silicon oxynitride, silicon oxycarbonitride, a layer of general formula SiNOC, especially SiN, in particular Si₃N₄.

Most particularly, a base layer (predominantly) made of doped or undoped silicon nitride Si₃N₄ may be preferred. Silicon nitride is deposited very rapidly and forms an excellent barrier to alkali metals.

As a layer that promotes the adhesion of the metal grid material (silver, gold), especially onto glass, it is possible to choose a layer based on NiCr, Ti, Nb, Al, a single or mixed metal oxide, doped or undoped, (ITO, etc.), a layer, for example, having a thickness less than or equal to 5 nm.

When the substrate is hydrophobic, it is possible to add a hydrophilic layer such as a silica layer.

The mask according to the invention therefore makes it possible to envision, at a lower cost, grid shapes and sizes different from the regular grids having a geometric pattern while retaining the irregular character of the conductive network that is already known but which does not form a grid.

For the manufacture of a grid from the mask such as defined previously, the deposition of a material known as a grid material is carried out, (especially) through the interstices of said mask, until a fraction of the depth of the interstices is filled.

The masking layer (which is optionally a first layer) is removed to reveal the grid based on said grid material (one or more layers).

The arrangement of the strands may then be substantially the replica of that of the network of openings.

Preferably, the removal is carried out via a liquid route, by a solvent that is inert for the grid, for example with water, acetone or alcohol (optionally when hot and/or assisted by ultrasounds). It is possible to clean the network of interstices prior to the deposition of the grid material being carried out.

In preferred embodiments of the invention, it is possible to optionally resort, in addition, to one and/or the other of the following arrangements

the deposition of the grid material fills both a fraction of the mask openings, also covering the surface of the mask; and

the deposition of the grid material is an atmospheric pressure deposition, especially by plasma, a deposition under vacuum, by sputtering, by evaporation.

It is thus possible to then choose one or more deposition techniques that can be carried out at ambient temperature and/or that are simple (especially more simple than a catalytic deposition that inevitably requires a catalyst) and/or that gives dense deposits.

The material deposited in the interstices may be chosen from electrically conductive materials.

The grid material may be electrically conductive and an electrically conductive material is deposited onto the grid material by electrolysis.

The deposition is thus to be optionally completed by an electrolytic recharge using an electrode made of Ag, Cu, Au or another usable metal with high conductivity.

When the substrate is insulating, the electrolytic deposition may be carried out either before or after removal of the mask.

By varying the B/A ratio (space between the strands (B) to the width of the strands (A) (size of the strands)) haze values between 1 and 20% are obtained for the grid.

The invention also relates to a substrate bearing an irregular grid, that is to say a two-dimensional and meshed network of strands with random, aperiodic meshes (closed units).

This grid may especially be formed from the mask that has already been defined previously.

The grid may have one or more of the following characteristics:

a ratio of the (average) space between the strands (B) to the submillimetric (average) width of the strands (A) between 7 and 40;

the units of the grid are random (aperiodic) and of diverse shape and/or size;

meshes delimited by the strands have three and/or four and/or five sides, for example mostly four sides;

the grid has an aperiodic (or random) structure in at least one direction, preferably in two directions;

for most, or even all, of the meshes in a given region or over the entire surface, the difference between the largest dimension characteristic of the mesh and the smallest dimension characteristic of the mesh is less than 2;

for most, or even all, of the meshes, the angle between two adjacent sides of one mesh may be between 60° and 110°, especially between 80° and 100°;

the difference between the maximum width of the strands and the minimum width of the strands is less than 4, or even less than or equal to 2, in a given grid region, or even over the majority or all of the surface;

the difference between the maximum mesh dimension (space between strands forming a mesh) and the minimum mesh dimension is less than 4, or even less than or equal to 2, in a given grid region, or even over the majority or all of the surface;

the content of non-sealed mesh and/or of cut strand (“blind”) segment is less than 5%, or even less than or equal to 2%, in a given grid region, or even over the majority or all of the surface, i.e. a limited or even almost zero network rupture;

for the most part, the strand edges are constantly spaced, in particular substantially linear, parallel, on a scale of 10 μm (for example observed with an optical microscope with a magnification of 200).

The grid according to the invention may have isotropic electrical properties.

Unlike the network conductor with a favored direction, the irregular grid according to the invention may not diffract a point light source.

The thickness of the strands may be substantially constant or be wider at the base.

The grid may comprise a main network with strands (optionally that are approximately parallel) and a secondary network of strands (that are optionally approximately perpendicular to the parallel network).

The grid may be deposited over at least one surface portion of the substrate, especially a substrate having a glass function, made of a plastic or an inorganic material, as already indicated.

The grid may be deposited onto a sublayer that is a hydrophilic layer and/or a layer that promotes adhesion and/or a barrier layer and/or a decorative layer as already indicated.

The electrically conductive grid may have a sheet resistance between 0.1 and 30 ohms/square. Advantageously, the electrically conductive grid according to the invention may have a sheet resistance less than or equal to 5 ohms/square, or even less than or equal to 1 ohm/square, or even 0.5 ohm/square, especially for a grid thickness greater than or equal to 1 μm, and preferably less than 10 μm or even less than or equal to 5 μm.

The light transmission of the substrate coated with the grid is greater than or equal to 50%, more preferably still greater than or equal to 70%, especially between 70% and 86%.

The B/A ratio may be different, for example at least double, in a first grid region and in a second grid region.

The first and second regions may be of different or equal shape and/or of different or equal size.

With a variable mesh opening/strand size ratio it is therefore possible to create zones with:

a light transmission gradient; and

an electric power gradient (application in heating, deicing, production of homogeneous heat flow over non-rectangular surfaces).

The light transmission of the network depends on the B/A ratio of the average distance between the strands B to the average width of the strands A.

Preferably, the B/A ratio is between 5 and 15, more preferably still around 10, to easily retain the transparency and facilitate the manufacture. For example, B and A are respectively equal to around 50 μm and 5 μm.

In particular, an average strand width A is chosen between 100 nm and 30 μM, preferably less than or equal to 10 μm, or even 5 μM in order to limit their visibility and greater than or equal to 1 μm to facilitate the manufacture and to easily retain a high conductivity and a transparency.

In particular, it is additionally possible to choose an average distance between strands B that is greater than A, between 5 μM and 300 μM, or even between 20 and 100 μm, to easily retain the transparency.

The thickness of the strands may be between 100 nm and 5 μm, especially micron-sized, more preferably still from 0.5 to 3 μm to easily retain a transparency and a high conductivity.

The grid according to the invention may be over a large surface area, for example a surface area greater than or equal to 0.02 m², or even greater than or equal to 0.5 m² or to 1 m².

The substrate may be flat or curved, and additionally rigid, flexible or semi-flexible.

Its main faces may be rectangular, square or even of any other shape (round, oval, polygonal, etc.). This substrate may be of a large size, for example having a surface area greater than 0.02 m², or even 0.5 m² or 1 m², with a lower electrode substantially occupying the surface (apart from the structuring zones).

The substrate may be substantially transparent, inorganic or made of a plastic such as polycarbonate PC or polymethyl methacrylate PMMA, or else PET, polyvinyl butyral PVB, polyurethane PU, polytetraflouroethylene PTFE, etc.

The substrate is preferably glass, especially made of soda-lime-silica glass.

Within the meaning of the invention, a substrate has a glass function when it is substantially transparent, and when it is based on minerals (for example, a soda-lime-silica glass) or when it is based on a plastic (such as polycarbonate PC or on polymethyl methacrylate PMMA).

The grid according to the invention may be used, in particular, as a lower electrode (closest to the substrate) for an organic light-emitting device (OLED), especially a bottom-emitting OLED or a bottom- and top-emitting OLED.

A multiple laminated glazing unit (lamination interlayer of EVA, PU, PVB, etc. type) may incorporate a substrate bearing the grid according to the invention.

According to yet another aspect of the invention, it targets the use of a grid such as described previously as:

an active layer (single-layer or multilayer electrode) in an electrochemical and/or electrically controllable device having variable optical and/or energy properties, for example a liquid crystal device or a photovoltaic device, or else an organic light-emitting device, a flat-lamp device;

an active (heating) layer of a heating device;

an electromagnetic shielding device; or

any other device requiring an (optionally (semi)-transparent) electrically conductive layer.

The invention will now be described in greater detail using nonlimiting examples and figures:

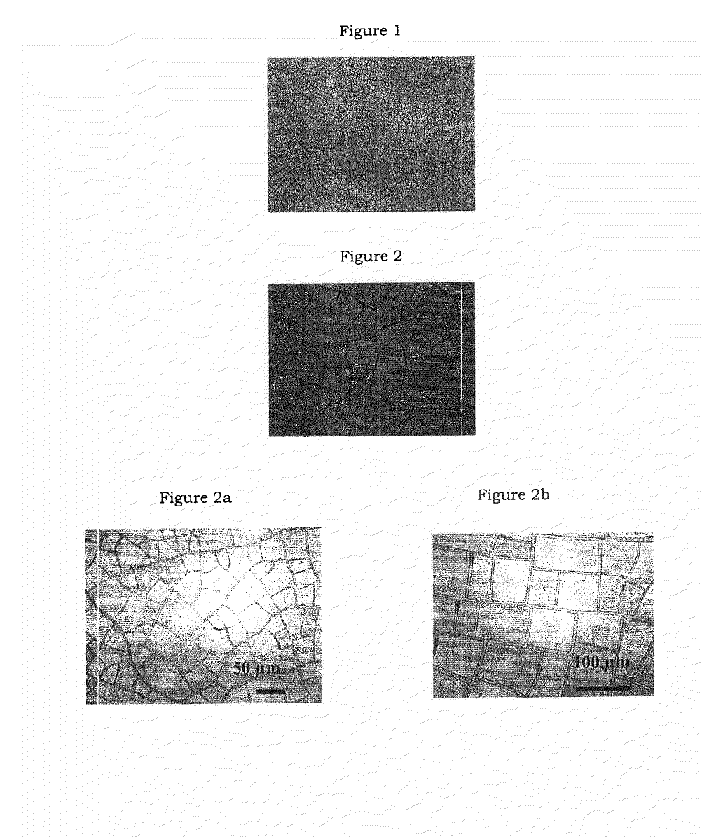

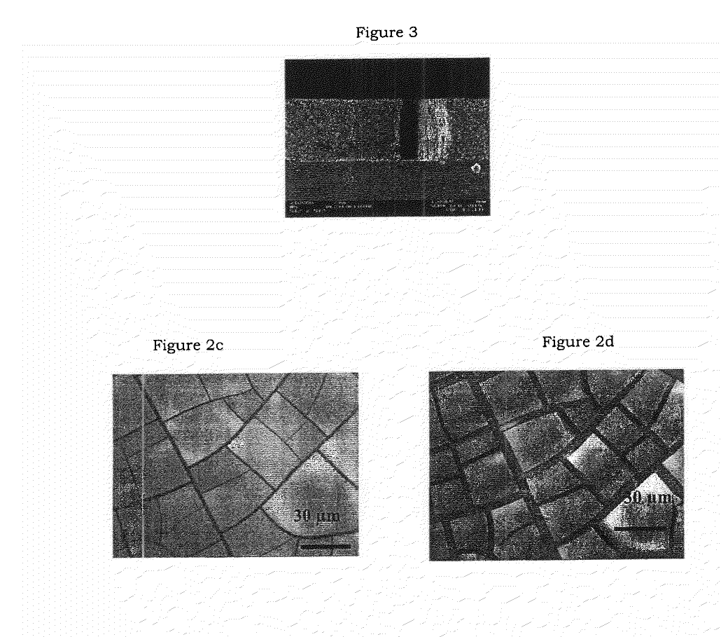

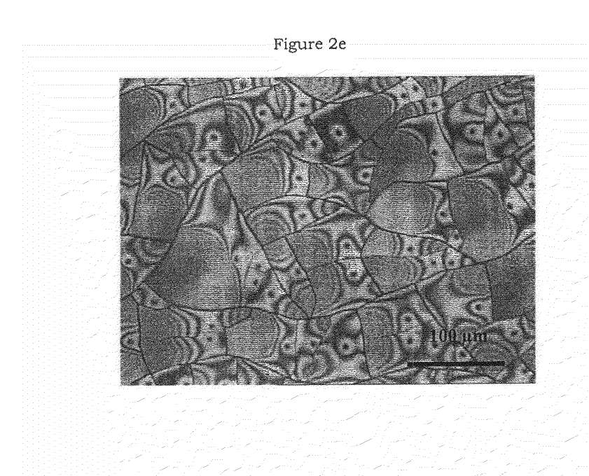

FIGS. 1 to 2e represent examples of masks obtained by the process according to the invention;

FIG. 3 is a SEM view illustrating the profile of the crack;

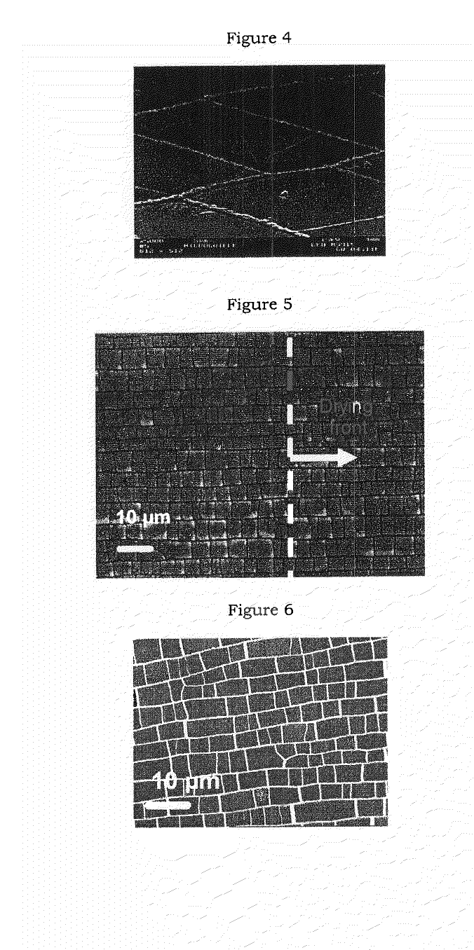

FIG. 4 represents a top view of a grid;

FIGS. 5 and 6 represent masks with different drying fronts;

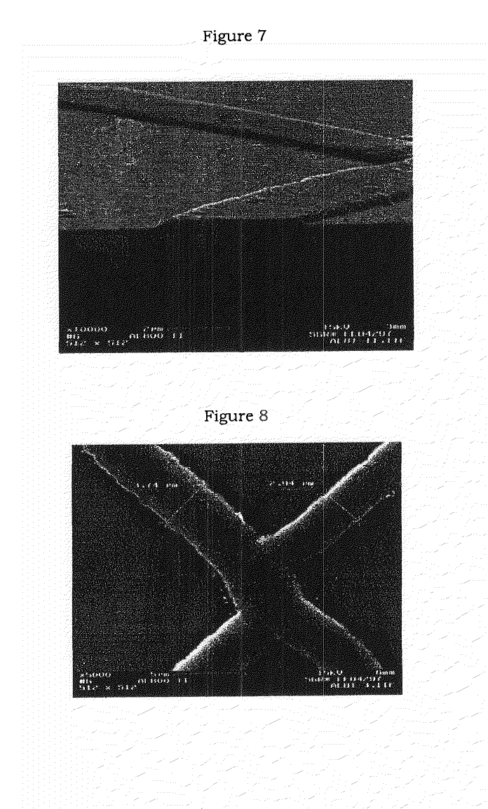

FIGS. 7 and 8 represent partial SEM views of a grid; and

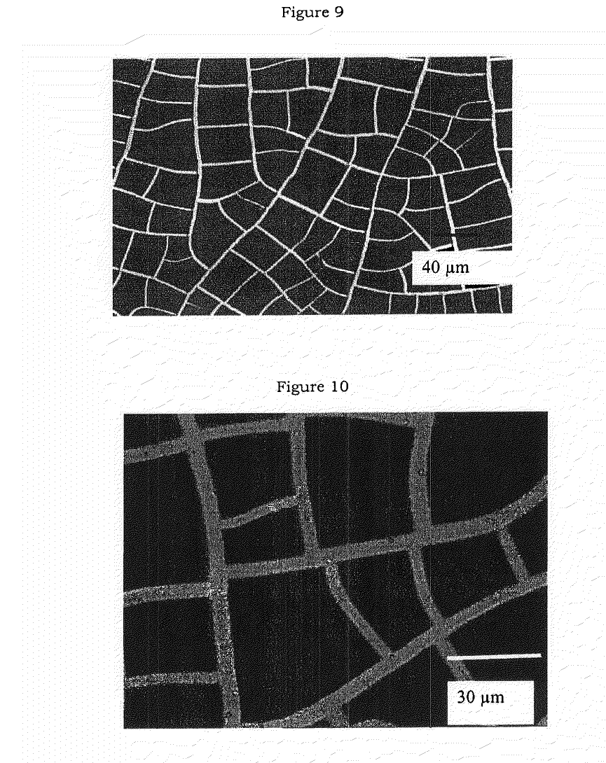

FIGS. 9 and 10 represent top views of grids.

Deposited onto a portion of a substrate having a glass function, by a wet route technique, by spin coating, was a simple emulsion of colloidal particles based on an acrylic copolymer that was stabilized in water at a concentration of 40 wt %, a pH of 5.1 and having a viscosity equal to 15 mPa·s. The colloidal particles had a characteristic dimension between 80 and 100 nm and were sold by DSM under the name NEOCRYL XK 52® and had a T_{g} equal to 115° C.

Drying of the layer incorporating the colloidal particles was then carried out so as to evaporate the solvent and form the interstices. This drying could be carried out by any suitable process and preferably at a temperature below the T_{g} (drying in hot air, etc.), for example at ambient temperature.

During this drying step, the system rearranges itself and forms patterns, exemplary embodiments of which are represented in FIGS. 1 and 2 (400 μm×500 μm views).

A stable mask is obtained without resorting to annealing, having a structure characterized by the (average) strand width subsequently referred to as A (in fact the size of the strand) and the (average) space between the strands subsequently referred to as B. This stabilized mask will subsequently be defined by the ratio B/A.

A two-dimensional network of interstices is obtained, meshed with little rupture of the meshes.

The influence of the temperature on drying was evaluated. Drying at 10° C. under 20% RH resulted in an 80 μm mesh (FIG. 2a), whereas drying at 30° C. under 20% RH resulted in a 130 μm mesh (FIG. 2b).

The influence of the drying conditions, especially the degree of humidity, was evaluated. The layer based on XK52 was this time deposited by flow coating which gave a variation in thickness between the bottom and the top of the sample (from 10 μm to 20 μm) resulting in a variation of the mesh size. The higher the humidity was, the smaller B was.

| Drying | Position | Mesh size B (μm) |
|---|---|---|
| 10° C. - 20% | top | 65 |
| humidity | | |
| 10° C. - 20% | bottom | 80 |
| humidity | | |
| 10° C. - 80% | top | 45 |
| humidity | | |
| 10° C. - 80% | bottom | 30 |
| humidity | | |
| 30° C. - 20% | top | 60 |
| humidity | | |
| 30° C. - 20% | bottom | 130 |
| humidity | | |
| 30° C. - 80% | top | 20 |
| humidity | | |
| 30° C. - 80% | bottom | 45 |
| humidity | | |

This B/A ratio was also modified by adjusting, for example, the friction coefficient between the compacted colloids and the surface of the substrate, or else the size of the nanoparticles, or even also the evaporation rate, or the initial particle concentration, or the nature of the solvent, or the thickness that was dependent on the deposition technique, etc.

In order to illustrate these various possibilities, an experimental design is given below with 2 concentrations of the colloid solution (C₀ and 0.5×C₀) and various thicknesses deposited by adjusting the ascent rate of the dip coater. It is observed that it is possible to change the B/A ratio by changing the concentration and/or the drying rate. The results are given in the following table:

| | Ascent rate | B: space | A: width | |
|---|---|---|---|---|
| | of the dip | between | of the | |
| Weight | coater | the strands | strands | B/A |
| concentration | (cm/min) | (μm) | (μm) | ratio |
| 20% | 5 | 25 | 3 | 8.4 |
| 20% | 10 | 7 | 1 | 7 |
| 20% | 30 | 8 | 1 | 8 |
| 20% | 60 | 13 | 1.5 | 8.6 |
| 40% | 5 | 50 | 4 | 12.5 |
| 40% | 10 | 40 | 3.5 | 11.4 |
| 40% | 30 | 22 | 2 | 11 |
| 40% | 60 | 25 | 2.2 | 11.4 |

The colloid solution was deposited at the concentration of C₀=40% by using film-drawers of various thicknesses. These experiments show that the size of the strands and the distance between the strands can be varied by adjusting the initial thickness of the colloid layer.

| Thickness | | B: space | A: width | |
|---|---|---|---|---|
| deposited | | between | of the | |
| by the film- | | the strands | strands | B/A |
| drawer (μm) | Weight % | (μm) | (μm) | ratio |
| 30 | 40 | 20 | 2 | 10 |
| 60 | 40 | 55 | 5 | 11 |
| 90 | 40 | 80 | 7 | 11.4 |
| 120 | 40 | 110 | 10 | 11.1 |
| 180 | 40 | 200 | 18 | 11.1 |
| 250 | 40 | 350 | 30 | 11.6 |

Finally, the surface roughness of the substrate was modified by etching, with atmospheric plasma, the surface of the glass via a mask of Ag nodules. This roughness was of the order of magnitude of the size of the contact zones with the colloids which increased the friction coefficient of these colloids with the substrate. The following table shows the effect of changing the friction coefficient on the B/A ratio and the morphology of the mask. It appears that smaller mesh sizes at an identical initial thickness and a B/A ratio which increases are obtained.

| | Ascent rate | B: space | A: width | |
|---|---|---|---|---|
| | of the dip | between | of the | |
| Nanotexturing | coater | the strands | strands | B/A |
| treatment | (cm/min) | (μm) | (μm) | ratio |
| Yes | 5 | 38 | 2 | 19 |
| Yes | 10 | 30 | 1.75 | 17.2 |
| Yes | 30 | 17 | 1 | 17 |
| Yes | 60 | 19 | 1 | 17.4 |
| Reference | 5 | 50 | 4 | 12.5 |
| Reference | 10 | 40 | 3.5 | 11.4 |
| Reference | 30 | 22 | 2 | 11 |
| Reference | 60 | 25 | 2.2 | 11.4 |

In another exemplary embodiment, the dimensional parameters of the network of interstices obtained by spin coating of one and the same emulsion containing the colloidal particles previously described are given below. The various rotational speeds of the spin-coating device modify the structure of the mask.

| | B: space | A: width | |
|---|---|---|---|
| | between | of the | |
| Rotational | the strands | strands | B/A |
| speed (rpm) | (μm) | (μm) | ratio |
| 200 | 40 | 2 | 20 |
| 400 | 30 | 2 | 15 |
| 700 | 20 | 1 | 20 |
| 1000 | 10 | 0.5 | 20 |

The effect of the propagation (cf. FIGS. 5 and 6) of a drying front on the morphology of the mask was studied. The presence of a drying front made it possible to create a network of approximately parallel interstices, the direction of which was perpendicular to this drying front. There was, on the other hand, a secondary network of interstices approximately perpendicular to the parallel network, for which the location and the distance between the strands were random.

At this stage of the implementation of the process, a mask was obtained.

A morphological study of the mask showed that the interstices had a straight crack profile. Reference can be made to FIG. 3 which is a transverse view of the mask obtained using SEM.

The crack profile represented in FIG. 3 has a particular advantage for:

depositing, especially in a single step, a large thickness of material; and

retaining a pattern, in particular of large thickness, that conforms to the mask after having removed the latter.

The mask thus obtained may be used as is or modified by various post-treatments. For example, according to this configuration, there are no colloidal particles at the bottom of the cracks; there will therefore be a maximum adhesion of the material that is introduced in order to fill the crack (this will be described in detail later on in the text) with the substrate having a glass function.

The inventors have furthermore discovered that the use of a plasma source as a source for cleaning the organic particles located at the bottom of the crack made it possible, subsequently, to improve the adhesion of the material being used as the grid.

As an exemplary embodiment, cleaning using a plasma source at atmospheric pressure, having a plasma spray based on a mixture of oxygen and helium, enabled both the improvement of the adhesion of the material deposited at the bottom of the interstices and the widening of the interstices. A plasma source of trademark ATOMFLOW, sold by Surfx, could be used.

In another embodiment, a simple emulsion of colloidal particles based on an acrylic copolymer stabilized in water at a concentration of 50 wt %, a pH of 3 and a viscosity equal to 200 mPa·s was deposited. The colloidal particles had a characteristic dimension of around 118 nm and were sold by DSM under the trademark NEOCRYL XK 38® and had a T_{g} equal to 71° C. The network obtained is shown in FIG. 2c.

The influence of annealing on the network parameters, as compiled in the following table, was evaluated.

| | | Range of spaces | Range of the |
|---|---|---|---|
| | | between the | strand widths |
| Sample | Annealing | strands (μm) | (μm) |
| Reference | no | 50-100 | 3-10 |
| Annealed | 100° C. | 50-100 | 6-20 |
| sample | 5 min | | |
| Annealed | 100° C. | 50-100 | 10-25 |
| sample | 15 min | | |

Via compaction, the width of the strands doubles, or even triples as shown in FIG. 2d (sample treated at 100° C. for 15 min).

It is possible to locally, for example at the center, modify the mask with a focused IR lamp. It is thus possible to obtain a grid with an LT gradient.

In another embodiment, a 40% solution of colloidal silica having a characteristic dimension of around 10 to 20 nm, for example the product LUDOX® AS 40 sold by Sigma Aldrich, was deposited. The B/A ratio was around 30, as shown in FIG. 2e.

Typically, it is possible to deposit, for example, between 15% and 50% of colloidal silica in an organic (especially aqueous) solvent.

Starting from the mask according to the invention, a grid is produced. In order to do this, a material is deposited, through the mask, until the interstices are filled. The material is preferably chosen from electrically conductive materials such as aluminum, silver, copper, nickel, chromium, alloys of these metals, conductive oxides especially chosen from ITO, IZO, ZnO:Al; ZnO:Ga; ZnO:B; SnO₂:F; SnO₂:Sb; nitrides such as titanium nitride, carbides such as, for example, silicon carbide, etc.

This deposition phase may be carried out, for example, by magnetron sputtering or by vapor deposition. The material is deposited inside the network of interstices so as to fill the cracks. the filling being carried out to a thickness, for example, of around half the height of the mask.

In order to reveal the grid structure from the mask, a “lift off” operation is carried out. This operation is facilitated by the fact that the cohesion of the colloids results from weak van der Waals type forces (no binder, or bonding resulting via annealing). The colloidal mask is then immersed in a solution containing water and acetone (the cleaning solution is chosen as a function of the nature of the colloidal particles), then rinsed so as to remove all the parts coated with colloids. The phenomenon can be accelerated due to the use of ultrasounds to degrade the mask of colloidal particles and allow the complementary parts (the network of interstices filled by the material), which will form the grid, to appear.

Represented in FIG. 4 is a photograph, obtained using SEM, of a grid thus obtained.

Given below are the electrical and optical characteristics obtained for aluminum-based grids.

| | Rotational speed (rpm) | | | | | | | |
|---|---|---|---|---|---|---|---|---|
| | 200 | | 400 | | 700 | | 1000 | |
| Al thickness (nm) | 300 | 1000 | 300 | 1000 | 300 | 1000 | 300 | 1000 |
| Sheet R (Q/□) | 2.1 | 0.65 | 2.4 | 0.7 | 3 | 0.9 | 3.1 | 0.95 |
| % LT | 79.8 | 79.3 | 81.9 | 82.1 | 83.2 | 83.1 | 84.9 | 83.9 |
| % LR | 14.7 | 15.0 | 14.6 | 14.2 | 13.1 | 12.4 | 11.7 | 11.6 |

Due to this particular grid structure, it is possible to obtain, at a lower cost, an electrode that is compatible with electrically controllable systems while having high electrical conductivity properties.

FIGS. 7 and 8 show SEM views from above (in perspective) and in detail of the strands of an aluminum grid. It is observed that the strands have relatively smooth and parallel edges.

The electrode incorporating the grid according to the invention has an electrical resistivity between 0.1 and 30 ohms/square and an LT of 70 to 86%, which makes its use as a transparent electrode completely satisfactory.

Preferably, especially to achieve this level of resistivity, the metal grid has a total thickness between 100 nm and 5 μm.

In these thickness ranges, the electrode remains transparent, that is to say that it has a low light absorption in the visible range, even in the presence of the grid (its network is almost invisible owing to its dimensions).

The grid has an aperiodic or random structure in at least one direction that makes it possible to avoid diffractive phenomena and results in a light occultation of 15 to 25%.

For example, a network as represented in FIG. 4 having metal strands 700 nm in width spaced apart by 10 μm gives a substrate a light transmission of 80% compared with a light transmission of 92% when bare.

Another advantage of this embodiment consists in that it is possible to adjust the haze value in reflection of the grids.

For example, for an inter-strand spacing (dimension B) of less than 15 μm, the haze value is around 4 to 5%.

For a spacing of 100 μm, the haze value is less than 1%, with B/A being constant.

For a strand spacing (B) of around 5 μm and a strand size of 0.3 μm, a haze of around 20% is obtained. Beyond a haze value of 5%, it is possible to use this phenomenon as a means for removing light at the interfaces or a means of trapping light.

Before depositing the mask material, it is possible to deposit, especially by vacuum deposition, a sublayer that promotes the adhesion of the grid material.

For example, nickel and, as the grid material, aluminum are deposited. This grid is shown in FIG. 9.

For example, ITO, NiCr or else Ti and, as the grid material, silver are deposited.

In order to increase the thickness of the metal layer and thus reduce the electrical resistance of the grid, a deposition was carried out, by electrolysis (soluble anode method), of an overlayer of copper on the silver grid.

The glass covered with the adhesion-promoting sublayer and the silver grid by magnetron sputtering constitutes the cathode of the experimental device; the anode is formed by a copper plate. It has the role, by being dissolved, of keeping the concentration of Cu²⁺ ions, and thus the deposition rate, constant during the entire deposition process.

The electrolysis solution (bath) was formed from an aqueous solution of copper sulfate (CuSO₄.5H₂O=70 g/l) to which 50 ml of sulfuric acid (10N H₂SO₄) were added. The temperature of the solution during the electrolysis was 23±2° C.

The deposition conditions were the following: voltage ≦1.5 V and current ≦1 A.

The anode and the cathode, spaced 3 to 5 cm apart and having the same size, were positioned in parallel in order to obtain perpendicular field lines.

The copper layers were homogeneous on the silver grids. The thickness of the deposition increased with the electrolysis time and the current density and also the morphology of the deposition. The results are given in the table below and in FIG. 10.

| | 500 nm Ag | With | With |
|---|---|---|---|
| Sample | reference | 0.5 μm Cu | 1 μm Cu |
| LT (%) | 75 | 70 | 66-70 |
| Haze (%) | 2.5 | 3.0 | 3.0 |
| Sheet R (Ω) | 3 | 2 | 0.2 |

The SEM observations carried out on these grids show that the size of the meshes was 30 μm±10 μm and the size of the strands was between 2 and 5 μm.

As mentioned above, the invention may be applied to various types of electrochemical or electrically controllable systems within which the grid may be integrated as an active layer (for example, as an electrode). It relates more particularly to electrochromic systems, especially “all solid” ones (the term “all solid” being defined, within the context of the invention, in respect of the multilayer stacks for which all the layers are of inorganic nature) or “all polymer” ones (the term “all polymer” being defined, within the context of the invention, in respect of the multilayer stacks for which all the layers are of organic nature), or else for mixed or hybrid electrochromic systems (in which the layers of the stack are of organic nature and inorganic nature) or else liquid-crystal or viologen systems, or else light-emitting systems and flat lamps. The metal grid thus produced may also form a heating element in a windshield, or an electromagnetic shielding.

The invention also relates to the incorporation of a grid such as obtained from the production of the mask described previously in glazing, operating in transmission. The term “glazing” should be understood in the broad sense and encompasses any essentially transparent material, having a glass function, that is made of glass and/or of a polymer material (such as polycarbonate PC or polymethyl methacrylate PMMA). The carrier substrates and/or counter-substrates, that is to say the substrates flanking the active system, may be rigid, flexible or semi-flexible.

The invention also relates to the various applications that may be found for these devices, mainly as glazing or mirrors: they may be used for producing architectural glazing, especially exterior glazing, internal partitions or glazed doors. They may also be used for windows, roofs or internal partitions of modes of transport such as trains, planes, cars, boats and worksite vehicles. They may also be used for display screens such as projection screens, television or computer screens, touch-sensitive screens, illuminating surfaces and heated glazing.

1-37. (canceled)

38. A process for manufacturing a mask having submillimetric openings on a surface portion of a substrate by deposition and drying of a mask layer wherein:
a mask layer is deposited from a solution of colloidal particles that are stabilized and dispersed in a solvent; and
the mask layer is dried until a two-dimensional network of substantially straight-edged interstices that forms the mask is obtained, said mask having a random mesh of interstices in at least one direction.

39. The process as claimed in claim 38 wherein the substrate is glass.

40. The process as claimed in claim 38, wherein, since the particles have a given glass transition temperature T_{g}, the deposition and drying are carried out at a temperature below said temperature T_{g}.

41. The process as claimed in claim 40, wherein the deposition and drying are carried out at ambient temperature.

42. The process as claimed in claim 41 wherein the difference between the given glass transition temperature T_{g} of the particles and the drying temperature is greater than 10° C.

43. The process as claimed in claim 38, wherein the deposition and drying are carried out substantially at atmospheric pressure.

44. The process as claimed in claim 38, wherein the colloid solution comprises polymeric nanoparticles.

45. The process as claimed in claim 44 wherein the polymeric nanoparticles are selected from the group consisting of acrylic copolymers, styrenes, polystyrenes, poly(meth)acrylates, polyesters and mixtures thereof.

46. The process as claimed in claim 38, wherein the solution comprises mineral nanoparticles.

47. The process as claimed in claim 46 wherein the mineral nanoparticles are selected from the group consisting of silica, alumina and iron oxide.

48. The process as claimed in claim 38, wherein the solution is aqueous.

49. The process as claimed in claim 38, wherein by modifying the control parameters chosen from the friction coefficient between the compacted colloids and the surface of the substrate, the size of the nanoparticles, the evaporation rate, the initial particle concentration, the nature of the solvent, the thickness that is dependent on the deposition technique, and the degree of moisture, the submillimetric width of the strands A, the space between the strands B and/or the B/A ratio are adjusted.

50. The process as claimed in claim 38, wherein after drying, the mask is at least locally heated at a temperature above the T_{g} and below the melting temperature Tₘ.

51. The process as claimed in claim 38, wherein a differential drying is carried out.

52. The process as claimed in claim 38, wherein the deposition is carried out directly onto the substrate.

53. The process as claimed in claim 52, wherein the substrate is glass.

54. The process as claimed in claim 38, wherein, before the deposition of the mask layer, a sublayer chosen from a hydrophilic layer, a barrier layer, a layer for adhesion of a grid material, or a decorative layer is deposited on the substrate.

55. A method for manufacturing an irregular, submillimetric grid comprising depositing a grid material through a substrate bearing a mask obtained according to the process as claimed in claim 38.

56. The method as claimed in claim 55, wherein the irregular, submillimetric grid is electrically conductive.

57. A process for manufacturing an irregular submillimetric grid wherein the deposition of a grid material is carried out through the interstices of the mask obtained according to the process as claimed in claim 38, until a fraction of the depth of the interstices is filled.

58. The process for manufacturing a grid as claimed in claim 57, wherein the mask layer is removed to reveal the grid based on said grid material.

59. The process for manufacturing a grid as claimed in claim 58, wherein the mask layer is removed via a liquid solvent route.

60. The process for manufacturing a grid as claimed in claim 57, wherein the network of interstices is cleaned prior to the deposition of the grid material.

61. The process for manufacturing a grid as claimed in claim 57, wherein the network of interstices is cleaned using an atmospheric pressure plasma source.

62. The process for manufacturing a grid as claimed in claim 57, wherein the deposition of the grid material is an atmospheric pressure deposition, by plasma, or under vacuum, is by sputtering or by evaporation.

63. The process for manufacturing a grid as claimed in claim 57, wherein the grid material deposited into the interstices is chosen from electrically conductive materials.

64. The process for manufacturing a grid as claimed in claim 57, wherein the grid material is electrically conductive, and an electrically conductive material is deposited onto the grid material by electrolysis.

65. A substrate bearing an irregular submillimetric grid obtained by the manufacturing process as claimed in claim 57.

66. A substrate bearing an irregular submillimetric grid that is random in at least one direction, comprising a main network with first strands having a submillimetric width and a secondary network of second strands having a width smaller than the first strands.

67. The substrate bearing an irregular grid as claimed in claim 66, wherein the grid has a ratio of the space between the strands (B) to the submillimetric width of the strands (A) between 7 and 40.

68. The substrate bearing a grid as claimed in claim 66, wherein the units of the grid are random, aperiodic and of diverse shape and/or size.

69. The substrate bearing a grid as claimed in claim 66, wherein the grid has an aperiodic or random structure in at least one direction.

70. The substrate bearing a grid as claimed in claim 66, wherein, for most of the meshes, the difference between the largest dimension characteristic of the mesh and the smallest dimension characteristic of the mesh is less than or equal to 2.

71. The substrate bearing a grid as claimed in claim 66, wherein the difference between the maximum strand width and the minimum strand width is less than 4, in a given grid region, and/or the difference between the maximum mesh dimension and the minimum mesh dimension is less than 4, in a given grid region.

72. The substrate bearing a grid as claimed in claim 66, wherein, for most of the meshes, the degree of mesh rupture and/or of cut strands is less than 5%.

73. The substrate bearing a grid as claimed in claim 66, wherein the electrically conductive grid has a sheet resistance between 0.1 and 30 ohms/square.

74. The substrate bearing a grid as claimed in claim 66, wherein the grid is deposited directly or indirectly onto at least one surface portion of a substrate having a glass function, and made of a plastic or an inorganic material.

75. The substrate bearing a grid as claimed in claim 66, wherein the grid is deposited onto a sublayer and/or a layer for promoting the adhesion of the grid material and/or a barrier layer and/or a decorative layer.

76. The substrate bearing a grid as claimed in claim 75 wherein the sublayer is selected from the group consisting of a hydrophilic layer and a silica layer.

77. The substrate bearing a grid as claimed in claim 75 wherein the layer for promoting the adhesion of the grid material is selected from the group consisting of NiCr, Tᵢ, ITO, Al and Nb.

78. The substrate bearing a grid as claimed in claim 75 wherein the barrier layer is Si₃N₄ or SiO₂.

79. The substrate bearing a grid as claimed in claim 66, wherein the light transmission of the substrate covered with the grid is between 70% and 86%.

80. The substrate bearing a grid as claimed in claim 66, wherein the B/A ratio is different in a first grid region and in a second grid region.

81. The substrate bearing a grid as claimed in claim 66, wherein it comprises a light transmission gradient and/or an electric power gradient.

82. A multiple laminated glazing unit comprising the grid substrate as claimed in claim 66.

83. A heating layer or electrode, in an electrochemical and/or electrically controllable device having variable optical and/or energy properties and having liquid crystals, or a photovoltaic device, or an organic light-emitting device, or a heating device, or a flat lamp device, an electromagnetic shielding device, or any other device requiring a conductive, especially transparent, layer comprising the electrically conductive grid as claimed in claim 65.
